(19) United States
(12) Patent Application Publication
(10) Pub. No.: US 2024/0381625 A1
(43) Pub. Date: Nov. 14, 2024

(54) METHODS OF MANUFACTURING SEMICONDUCTOR DEVICE

(71) Applicant: SK hynix Inc., Gyeonggi-do (KR)

(72) Inventor: Heon Yong CHANG, Gyeonggi-do (KR)

(21) Appl. No.: 18/505,131

(22) Filed: Nov. 9, 2023

(30) Foreign Application Priority Data
May 9, 2023 (KR) 10-2023-0060182

(51) Int. Cl. H10B 12/00

(52) U.S. Cl. CPC H10B 12/482; H10B 12/09; H10B 12/50

(57) ABSTRACT

In a method of manufacturing a semiconductor device a substrate having a cell region and a peripheral region is prepared. A first cell-periphery structure including a conductive layer is formed over a surface of the substrate. In the cell region, a cell bit line trench is formed by patterning the first cell-periphery structure. A second cell-periphery structure including a second conductive layer is formed over the surface of the substrate. The second cell-periphery structure forms a cell bit line structure filling the cell bit line trench in the cell region, and is disposed over the first cell-periphery structure in the peripheral region. A periphery gate structure is formed by patterning the first and second cell-periphery structures in the peripheral region.

### CROSS-REFERENCE TO RELATED APPLICATIONS

The present application claims priority under 35 U.S.C. 119 (a) to Korean Application No. 10-2023-0060182, filed on May 9, 2023, which is incorporated herein by reference in its entirety.

### BACKGROUND

### 1. Technical Field

The present disclosure generally relates to methods of manufacturing semiconductor devices.

### 2. Related Art

As the integration degree of semiconductor devices increases and the line width decreases, the difficulty of a semiconductor process increases. In particular, in the case of a memory device, the probability of an occurrence of a defect may increase in a semiconductor process performed in a cell region having a relatively high integration degree between the cell region and a peripheral circuit region.

As an example, when a pattern structure having a high aspect ratio is formed in the cell region of the memory device, the probability of collapse of the patterned structure or occurrence of defective patterning in the structure may increase due to insufficient process margin in the patterning process. Accordingly, various studies are being conducted on a process capable of improving structural stability of the pattern structure when forming a pattern structure in a dense region in a semiconductor device.

### SUMMARY

In a method of manufacturing a semiconductor device according to one embodiment, a substrate having a cell region and a peripheral region may be provided. A first cell-periphery structure including a conductive layer may be formed over a surface of the substrate. In the cell region, a cell bit line trench may be formed by patterning the first cell-periphery structure. A second cell-periphery structure including a second conductive layer may be formed over the surface of the substrate. The second cell-periphery structure may form a cell bit line structure filling the cell bit line trench in the cell region, and be disposed over the first cell-periphery structure in the peripheral region. A periphery gate structure may be formed by patterning the first and second cell-periphery structures in the peripheral region.

In a method of manufacturing a semiconductor device according to another embodiment, a substrate having a cell region and a peripheral region may be provided. A cell gate structure buried in the substrate may be formed in the cell region. A cell contact plug and an interlayer insulation layer surrounding the cell contact plug may be formed over the substrate in the cell region. A first cell-periphery structure including a first conductive layer may be formed over an surface of the substrate. A cell bit line trench exposing the cell contact plug may be formed by patterning the first cell-periphery structure in the cell region. A second cell-periphery structure including a second conductive layer may be formed over the surface of the substrate. The second cell-periphery structure may form a cell bit line structure filling the cell bit line trench in the cell region, and be disposed over the first cell-periphery structure in the peripheral region. The first cell-periphery structure may be removed in the cell region. A periphery gate structure may be formed by patterning the first and second cell-periphery structures in the peripheral region.

In a method of manufacturing a semiconductor device according to another embodiment, a substrate having a first region and a second region may be provided. A first structure including a first conductive layer may be formed over a surface of the substrate. A trench may be formed by patterning the first structure in the first region. A second structure including a second conductive layer may be formed over a surface of the substrate. The second structure may form a first conductive line structure filling the trench in the first region, and be disposed over the first structure in the second region. A second conductive line structure may be formed by patterning the first and second structures in the second region.

### BRIEF DESCRIPTION OF THE DRAWINGS

FIG. 1 a cross-sectional view schematically illustrating a semiconductor device according to one embodiment of the present disclosure.

FIGS. 2 to 13 are cross-sectional views schematically illustrating a method of manufacturing a semiconductor device according to other embodiments of the present disclosure.

FIGS. 14 to 17 are cross-sectional views schematically illustrating a method of manufacturing a semiconductor device according to still other embodiments of the present disclosure, and a semiconductor device manufactured by the method.

FIGS. 18 and 19 are cross-sectional views schematically illustrating a method of manufacturing a semiconductor device according to yet other embodiments of the present disclosure, and a semiconductor device manufactured by the method.

### DETAILED DESCRIPTION

Hereinafter, embodiments of the present disclosure will be described in detail with reference to the accompanying drawings. In the drawings, in order to clearly express the components of each device, the sizes of the components, such as width and thickness of the components, are enlarged. The terms used herein may correspond to words selected in consideration of their functions in the embodiments, and the meanings of the terms may be construed to be different according to the ordinary skill in the art to which the embodiments belong. If expressly defined in detail, the terms may be construed according to their definitions. Unless otherwise defined, the terms (including technical and scientific terms) used herein have their plain and ordinary meaning as understood by one of ordinary skill in the art.

In addition, expression of a singular form of a word should be understood to include the plural forms of the word unless clearly used otherwise in the context. It will be understood that the terms “comprise”, “include”, or “have” are intended to specify the presence of a feature, a number, a step, an operation, a component, an element, a part, or combinations thereof, but not used to preclude the presence or possibility of addition one or more other features, numbers, steps, operations, components, elements, parts, or combinations thereof. It will be understood that when an element is referred to as being “disposed” on, or “connected” to, another element, it can be directly disposed on, or connected to, the other element, or intervening elements may also be present. In contrast, when an element is referred to as being “directly disposed” on or “directly connected” to, another element, there are no intervening elements present.

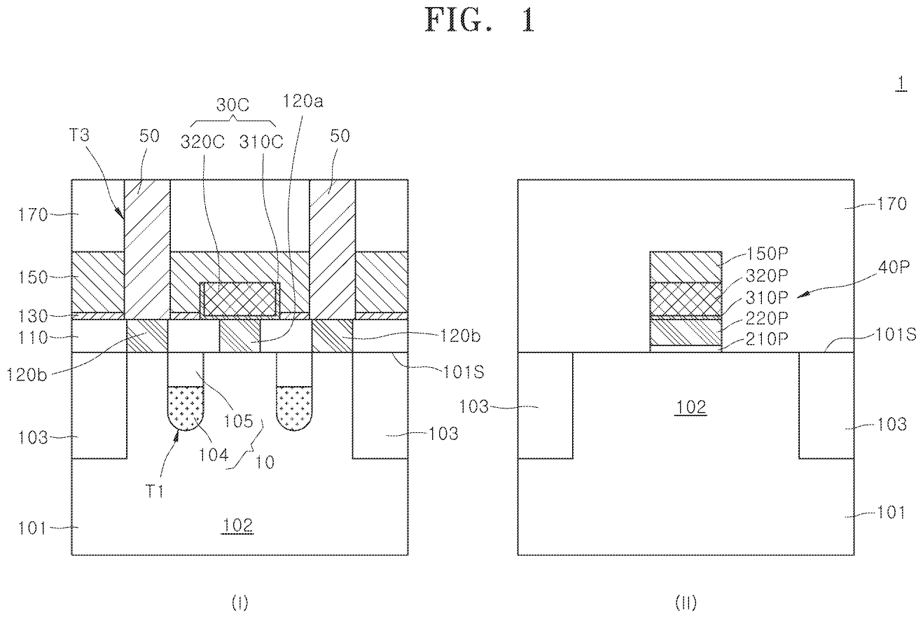

FIG. 1 a cross-sectional view schematically illustrating a semiconductor device 1 according to one embodiment of the present disclosure. The semiconductor device 1 may be a dynamic random access memory (DRAM) device including integrated circuits disposed in a cell region I and a peripheral region II.

Referring to FIG. 1, the semiconductor device 1 may include a substrate 101 including the cell region I and the peripheral region II. The semiconductor device 1 may include buried cell gate structures 10, cell contact plugs 120a and 120b, a cell bit line structure 30C, and storage node contact plugs 50, which are disposed in the cell region I of the substrate 101. The semiconductor device 1 may include a periphery gate structure 40P disposed in the peripheral region II.

Referring to the cell region I of FIG. 1, the substrate 101 may include a device isolation layer 103 that defines an active region 102. Each of the buried cell gate structure 10 may include a cell gate dielectric layer formed along an inner surface of a cell gate trench T1 formed in the substrate 101, a cell gate electrode layer 104 that buries a portion of the cell gate trench T1 in which the cell gate dielectric layer is formed, and a cell gate hard mask layer 105 that buries the remaining portion of the cell gate trench T1.

The cell contact plugs 120a and 120b may be disposed over an upper surface 101S of the substrate 101 in the cell region I. The cell contact plugs 120a and 120b may include a first contact plug 120a electrically connecting the active region 102 and the cell bit line structure 30C to each other, and second contact plugs 120b electrically connecting the active region 102 and the storage node contact plugs 50 to each other. Each of the cell contact plugs 120a and 120b may include a conductive material.

The cell contact plugs 120a and 120b may be disposed to be surrounded by a first interlayer insulation layer 110 over the upper surface 101S of the substrate 101. The first interlayer insulation layer 110 may include an insulating material. In one embodiment, the first interlayer insulation layer 110 may be formed of different material from the cell gate hard mask layer 105. For example, the cell gate hard mask layer 105 may include nitride, and the first interlayer insulation layer 110 may include oxide. An upper surface of each of the cell contact plugs 120a and 120b and an upper surface of the first interlayer insulation layer 110 may be positioned at substantially the same level. An etch stop layer 130 may be disposed over the first interlayer insulation layer 110. In one embodiment, the etch stop layer 130 may be formed of different material from the first interlayer insulation layer 110. For example, the first interlayer insulation layer 110 may include oxide, and the etch stop layer 130 may include nitride.

The cell bit line structure 30C may be disposed to contact both the first contact plug 120a and the first interlayer insulation layer 110. The cell bit line structure 30C may have a shape of a pillar. The cell bit line structure 30C may include a bit line diffusion barrier layer 310C disposed on a bottom surface and a sidewall surface of the pillar, and a bit line conductive layer 320C filling the pillar. The cell bit line structure 30C may be disposed to extend in one direction parallel to the upper surface 101S of the substrate 101.

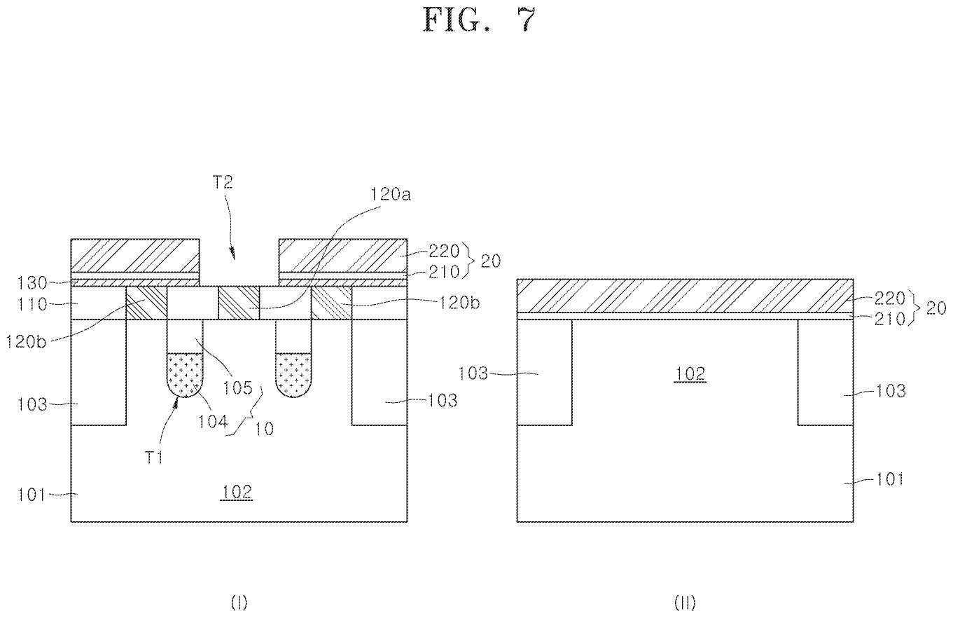

The cell bit line structure 30C may be disposed to be surrounded by a second interlayer insulation layer 150 disposed over the etch stop layer 130. The second interlayer insulation layer 150 may include, for example, nitride. The second interlayer insulation layer 150 may be disposed to contact the bit line diffusion barrier layer 310C and the bit line conductive layer 320C. As will be described later with reference to FIG. 7, because the cell bit line structure 30C may be processed through a damascene process for filling a cell bit line trench T2, a mask layer that assists bit line patterning, such as a conventional bit line hard mask layer, might not be disposed over the bit line conductive layer 320C.

Referring to the cell region I of FIG. 1, a third interlayer insulation layer 170 may be disposed over the second interlayer insulation layer 150. In addition, the storage node contact plugs 50 may be disposed to be electrically connected to the second contact plugs 120b in the cell region I. The storage node contact plugs 50 may be disposed inside storage node contact holes T3 formed to penetrate the second and third interlayer insulation layers 150 and 170 and the etch stop layer 130.

Referring to the peripheral region II of FIG. 1, the periphery gate structure 40P may be disposed over the active region 102 of the substrate 101. The periphery gate structure 40P may include a periphery gate dielectric layer 210P, a first periphery gate electrode layer 220P, a gate diffusion barrier layer 310P, a second periphery gate electrode layer 320P, and a periphery gate hard mask layer 150 which are sequentially disposed over the upper surface 101S of the substrate 101. The periphery gate structure 40P may be covered by the third interlayer insulation layer 170 over the upper surface 101S of the substrate 101. According to a manufacturing method according to one embodiment to be described later, the gate diffusion barrier layer 310P of the periphery gate structure 40P may be formed in the same thin film deposition step as the bit line diffusion barrier layer 310C of the cell region I. In addition, the second periphery gate electrode layer 320P of the periphery gate structure 40P may be formed in the same thin film deposition step as the bit line conductive layer 320C of the cell region I. In addition, the periphery gate hard mask layer 150P of the periphery gate structure 40P may be formed in the same thin film deposition step as the second interlayer insulation layer 150 of the cell region I.

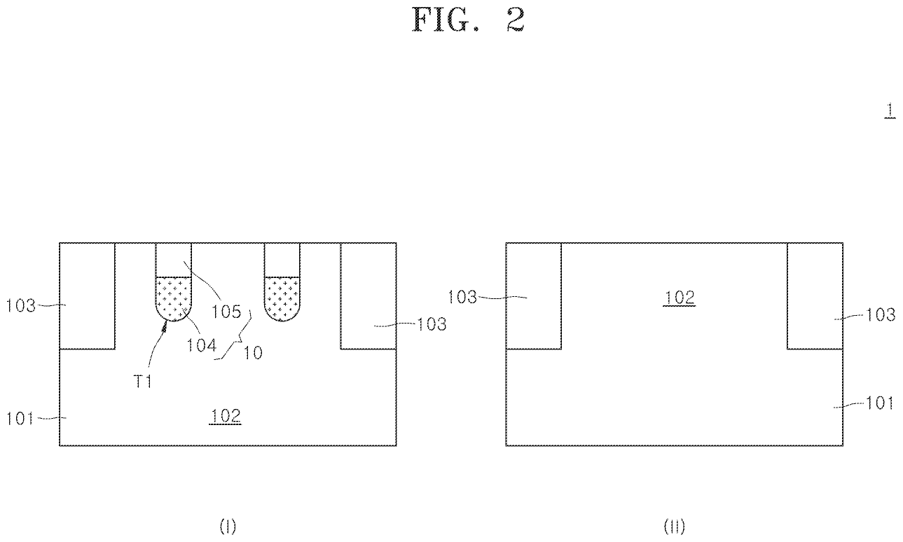

FIGS. 2 to 13 are cross-sectional views schematically illustrating a method of manufacturing a semiconductor device according to other embodiments of the present disclosure. The method of manufacturing the semiconductor device 1 related to FIGS. 2 to 13 may be applied to a method of manufacturing the semiconductor device 1 of FIG. 1.

Referring to FIG. 2, the substrate 101 having the cell region I and the peripheral region II may be provided. The substrate 101 may include a semiconductor material. For example, the substrate 101 may include one or more of silicon (Si), germanium (Ge), silicon germanium (SiGe), gallium arsenide (GaAs), and the like. The substrate 101 may be doped with an n-type dopant or a p-type dopant. In one embodiment, the substrate 101 may be a silicon (Si) substrate doped with a p-type dopant. Next, the device isolation layer 103 defining an active region 102 may be formed in the substrate 101. The device isolation layer 103 may be formed by a shallow trench isolation (STI) process.

Next, the cell gate trenches T1 may be formed in the substrate 101 of the cell region I. The cell gate dielectric layer may be formed along inner surfaces of the cell gate trenches T1, and a portion of each of the cell gate trenches T1 in which the cell gate dielectric layer is formed may be filled with a conductive material to form the cell gate electrode layer 104. Next, the remaining portion of each of the cell gate trenches T1 may be filled with an insulating material to form the cell gate hard mask layer 105. As a result, the buried cell gate structures 10 each including the cell gate dielectric layer, the cell gate electrode layer 104, and the cell gate hard mask layer 105 may be formed.

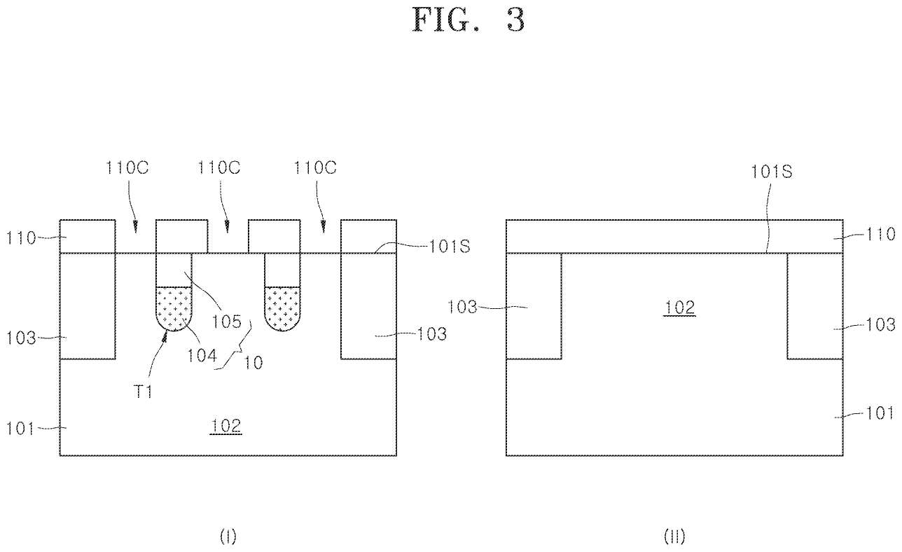

Referring to FIG. 3, the first interlayer insulation layer 110 may be formed over the surface of the substrate 101 and may be formed across the entirety of substrate 101. That is, the first interlayer insulating layer 110 may be formed over the upper surface 101S of the substrate 101 in the cell region I and the peripheral region II. In one embodiment, the first interlayer insulation layer 110 may be formed of a material different from that of the cell gate hard mask layer 105. For example, the cell gate hard mask layer 105 may include nitride, and the first interlayer insulation layer 110 may include oxide. Next, the first interlayer insulation layer 110 formed in the cell region I may be selectively etched to form cell open contact holes 110C exposing the active region 102 of the substrate 101.

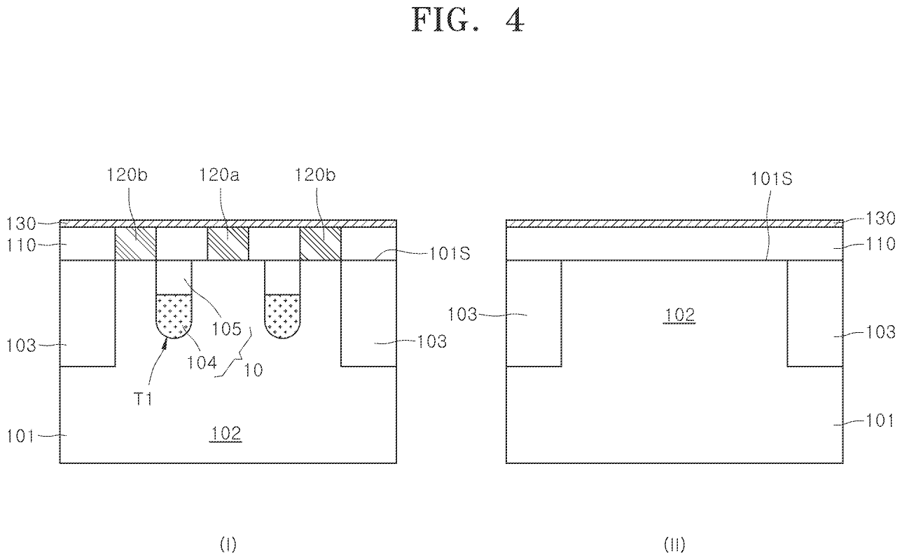

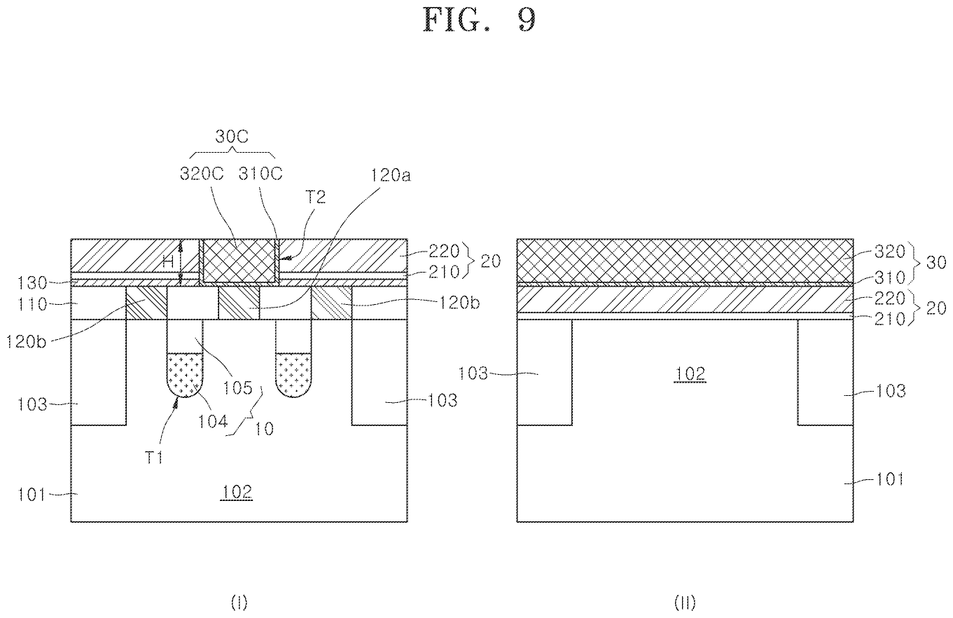

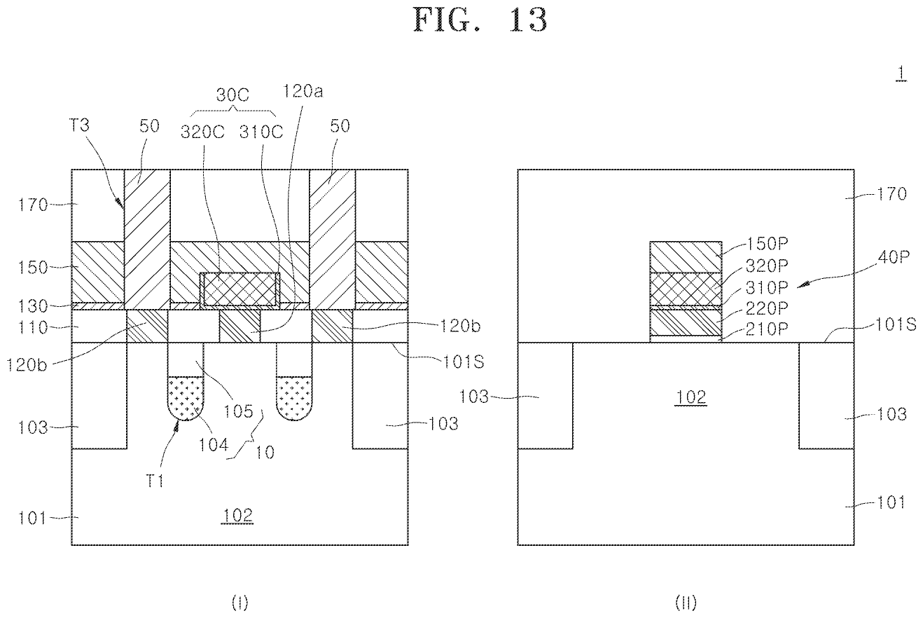

Referring to FIG. 4, in the cell region I, the cell open contact holes 110C may be filled with a conductive material to form the cell contact plugs 120a and 120b. Accordingly, the first interlayer insulation layer 110 may be disposed to surround the cell contact plugs 120a and 120b over the upper surface 101S of the substrate 101. The cell contact plugs 120a and 120b may include the first contact plug 120a connected to the cell bit line structure (see 30C, refer to FIG. 9) and the second contact plugs 120b connected to the storage node contact plugs (see 50, refer to FIG. 13).

In one embodiment, in a process of forming the cell contact plugs 120a and 120b, first, the cell open contact holes 110C may be filled with a conductive material layer, and the conductive material layer may also be formed over the first interlayer insulation layer 110 outside of the cell open contact holes 110C. Subsequently, a planarization process may be performed to remove the conductive material layer to expose the first interlayer insulation layer 110, thereby forming the cell contact plugs 120a and 120b. The planarization process may include, for example, chemical mechanical polishing (CMP).

As a result of the planarization process, upper surfaces of the cell contact plugs 120a and 120b and an upper surface of the first interlayer insulation layer 110 may be positioned on the same plane. Meanwhile, in the peripheral region II, the conductive material layer formed over the first interlayer insulation layer 110 may be removed by the planarization process.

Subsequently, the etch stop layer 130 may be formed over the surface of the substrate 101 or over the entirety of substrate 101. The etch stop layer 130 may be formed over the cell contact plugs 120a and 120b and over the first interlayer insulation layer 110 in the cell region I, and may be formed over the first interlayer insulation layer 110 in the peripheral region II. In one embodiment, the etch stop layer 130 may be formed of a material different from that of the first interlayer insulating layer 110. For example, the first interlayer insulation layer 110 may include oxide, and the etch stop layer 130 may include nitride.

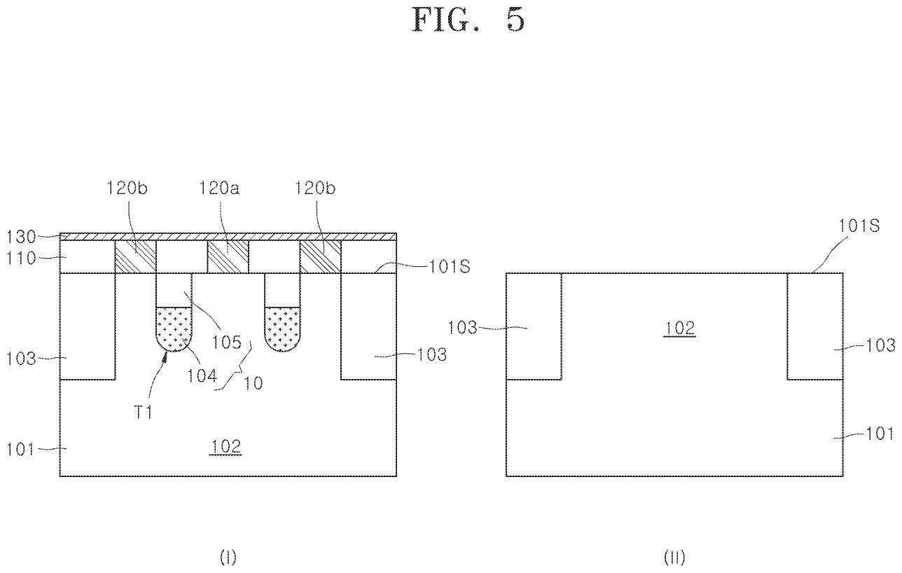

Referring to FIG. 5, in the peripheral region II, the etch stop layer 130 and the first interlayer insulation layer 110 may be sequentially etched to expose the substrate 101. In one embodiment, an etching process may be performed in a state in which the cell region I is masked using a mask pattern, and the peripheral region II is exposed, thereby selectively removing the etch stop layer 130 and the first interlayer insulation layer 110 in the peripheral region II.

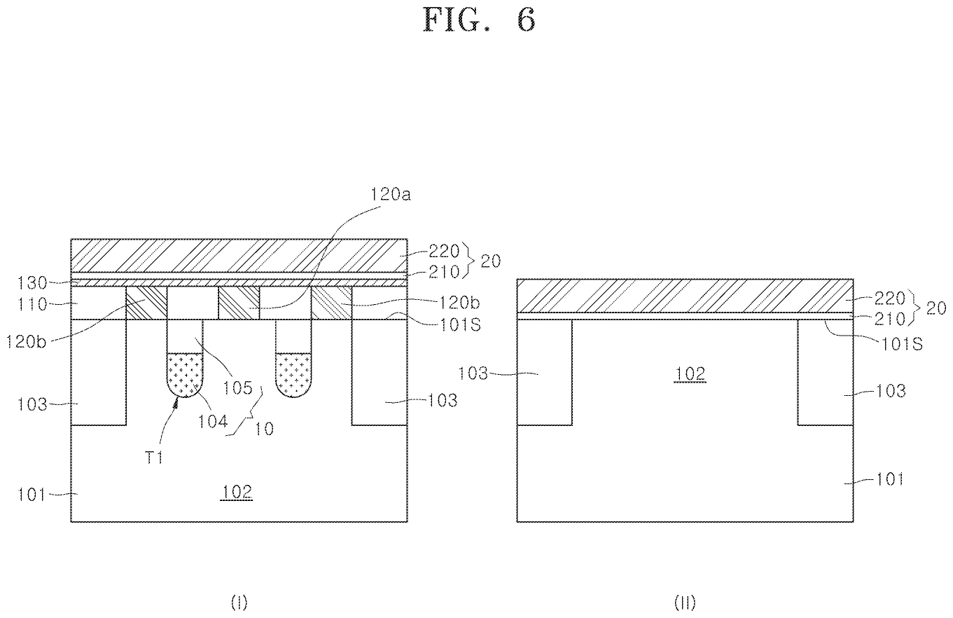

Referring to FIG. 6, a first cell-periphery structure 20 may be formed over the substrate 101. The first cell-periphery structure 20 may include a dielectric layer 210 and a first conductive layer 220 formed over the dielectric layer 210. In one embodiment, in the cell region I, the dielectric layer 210 may be formed over the etch stop layer 130, and the first conductive layer 220 may be formed over the dielectric layer 210 over the surface of the substrate 101 or over the entirety of the substrate 101. In the peripheral region II, the dielectric layer 210 may be formed over the upper surface 101S of the substrate 101, and the first conductive layer 220 may be formed over the dielectric layer 210.

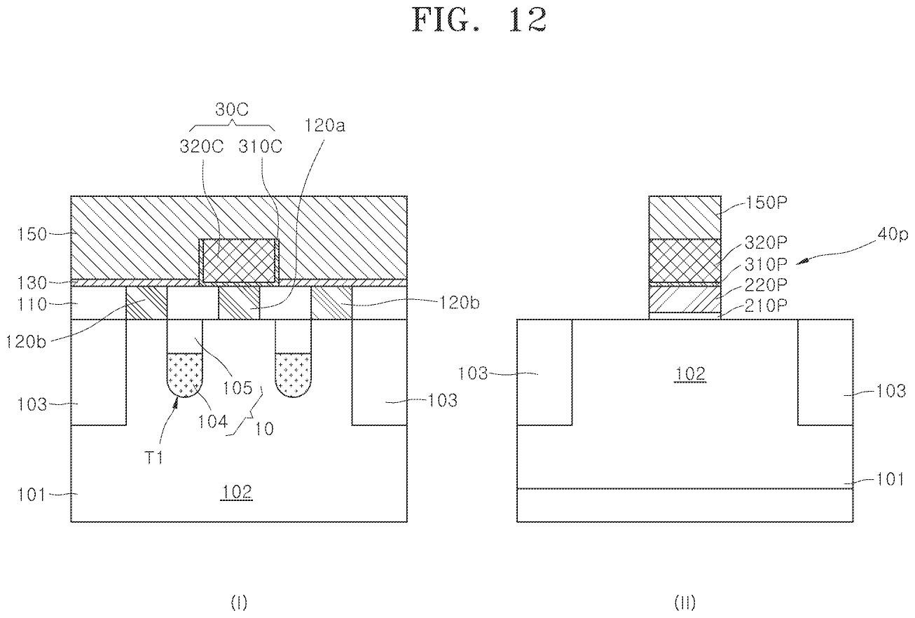

Meanwhile, through subsequent processes, the dielectric layer 210 may function as the periphery gate dielectric layer 210P of the periphery gate structure 40P (refer to FIG. 12) in the peripheral region II. Accordingly, the physical property and thickness of the dielectric layer 210 may be determined in consideration of operational characteristics of the periphery gate dielectric layer 210P. In addition, the first conductive layer 220 may function as the first periphery gate electrode layer 210P (refer to FIG. 12) of the periphery gate structure 40P in the peripheral region II. Accordingly, the physical property and thickness of the first conductive layer 220 may be determined in consideration of operational characteristics related to electrical conductivity of the first periphery gate electrode layer 210P. The dielectric layer 210 may include, for example, silicon oxide, silicon nitride, silicon oxynitride, aluminum oxide, hafnium oxide, zirconium oxide, hafnium zirconium oxide, or a combination of two or more thereof. The first conducive layer 220 may include, for example, polysilicon.

Referring to FIG. 7, in the cell region I, the first cell-periphery structure 20 and the etch stop layer 130 may be patterned to form the cell bit line trench T2. A process of patterning the first cell-periphery structure 20 and the etch stop layer 130 may be performed by forming an etch mask pattern over the first cell-periphery structure 20, and sequentially etching the first conductive layer 220, the dielectric layer 210, and the etch stop layer 130 exposed by the etch mask pattern. The first contact plug 120a and the first interlayer insulation layer 110 may be exposed by the cell bit line trench T2. The cell bit line trench T2 may extend in one direction parallel to the upper surface 101S of the substrate 101.

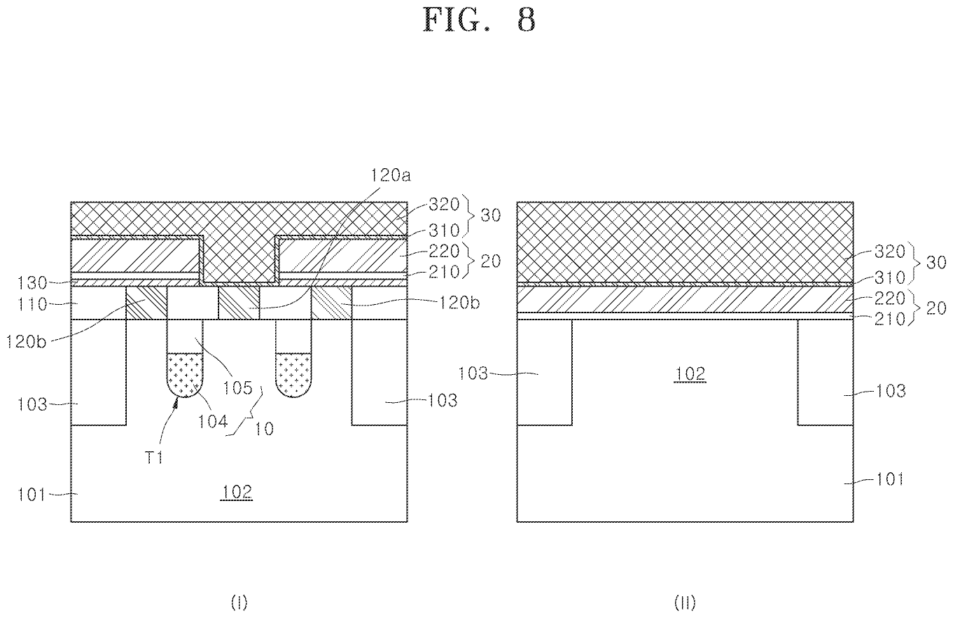

Referring to FIG. 8, in cell region I and peripheral region II, a second cell-periphery structure 30 may be formed over the substrate 101. The second cell-periphery structure 30 may include a barrier layer 310, and a second conductive layer 320 formed over the barrier layer 310 over the surface of the substrate 101 or over the entirety of the substrate 101. The barrier layer 310 may include, for example, titanium (Ti), titanium nitride (TiN), tungsten nitride (WN), tungsten silicon nitride (WSiN), or a combination of two or more thereof. The second conductive layer 320 may include, for example, tungsten (W).

In another embodiment, in the cell region I, the barrier layer 310 may be formed over an inner surface of the cell bit line trench T2 and an upper surface of the first cell-periphery structure 20 outside of the second cell bit line trench T2. Next, the second conductive layer 320 may be formed inside the cell bit line trench T2 in which the barrier layer 310 is formed and over an upper surface of the barrier layer 310 outside the cell bit line trench T2. Meanwhile, in the peripheral region II, the barrier layer 310 and the second conductive layer 320 may be sequentially formed over the first cell-periphery structure 20.

Referring to FIG. 9, a planarization process may be performed over the second cell-periphery structure 30 over the substrate 101. In this embodiment, in the cell region I, the second cell-periphery structure 30 (i.e., the second conductive layer 320 and the barrier layer 310) formed over the outside of the cell bit line trench T2 may be removed through the planarization process, so that the first cell-periphery structure 20 may be exposed. In addition, in the peripheral region II, the thickness of the second conductive layer 320 may be reduced through the planarization process.

As a result of the planarization process, in the cell region I, the cell bit line structure 30C may be formed. As described above, the cell bit line structure 30C may be formed by the damascene process. The cell bit line structure 30C may include a diffusion barrier layer 310C disposed over an inner surface of the cell bit line trench T2 and a bit line conductive layer 320C filling the cell bit line trench T2. The cell bit line structure 30C may have a height H corresponding to the sum of thicknesses of the etch stop layer 130 and the first cell-periphery structure 20 over the first interlayer insulation layer 110. The cell bit line structure 30C may extend in one direction parallel to the upper surface 101S of the substrate 101.

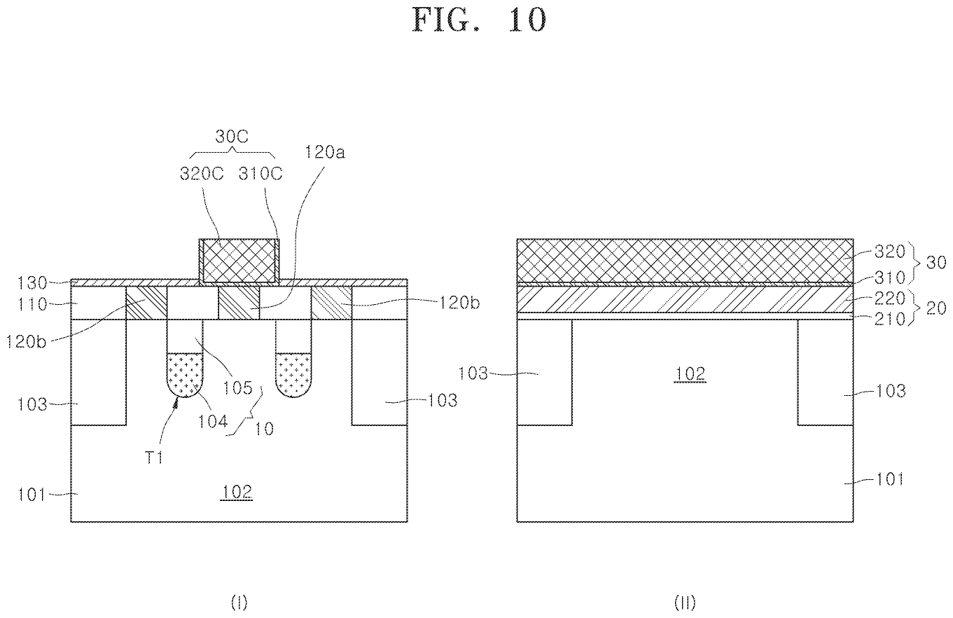

Referring to FIG. 10, in the cell region I, the first cell-peri structure 20 may be removed. According to this embodiment, a cell open mask pattern may be formed over the substrate 101 to cover the peripheral region II and to expose the cell region I. Next, in the exposed cell region I, the first cell-periphery structure 20 may be removed, and the etch stop layer 130 may be exposed by applying an etching method using an etching selectivity between the first cell-periphery structure 20 and the second cell-periphery structure 30.

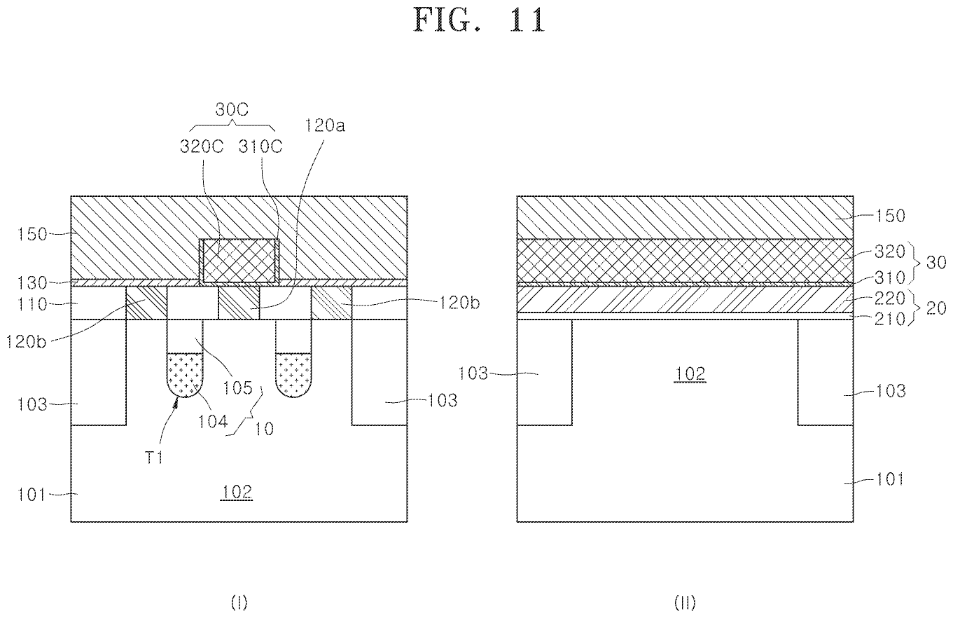

Referring to FIG. 11, the second interlayer insulation layer 150 may be formed over the surface of the substrate 101 or over the entirety of substrate 101. In the cell region I, the second interlayer insulation layer 150 may be formed to cover the cell bit line structure 30C over the etch stop layer 130. In the peripheral region II, the second interlayer insulation layer 150 may be formed over the second cell-periphery structure 30. The second interlayer insulation layer 150 may include, for example, nitride. In one embodiment, after the second interlayer insulation layer 150 is formed, a process of planarizing the second interlayer insulation layer 150 may additionally be performed. As a result, the upper surfaces of the second interlayer insulation layer 150 in the cell region I and the peripheral region II may be positioned at the same level.

Referring to FIG. 12, in the peripheral region II, the second interlayer insulation layer 150, the second cell-periphery structure 30, and the first cell-periphery structure 20 may be patterned to form the periphery gate structure 40P over the upper surface 101S of the substrate 101. More specifically, in this embodiment, a periphery gate mask pattern may be formed over the substrate 101 to cover the cell region I and to expose the peripheral region II. Next, in the peripheral region II, the second interlayer insulation layer 150, the second conductive layer 320, the barrier layer 310, the first conductive layer 220, and the dielectric layer 210 may be sequentially etched using the periphery gate mask pattern. In this case, the second interlayer insulation layer 150 may function as a hard mask layer for etching the first and second cell-periphery structures 20 and 30. As a result of etching, the periphery gate structure 40P may be formed.

The periphery gate structure 40P may include the periphery gate dielectric layer 210P, the first periphery gate electrode layer 220P, the gate diffusion barrier layer 310P, the second periphery gate electrode layer 320P, and the periphery gate hard mask layer 150P which are sequentially disposed over the upper surface 101S of the substrate 101.

Referring to FIG. 13, the third interlayer insulation layer 170 may be formed over the substrate 101. In the cell region I, the third interlayer insulation layer 170 may be formed over the second interlayer insulation layer 150. In the peripheral region II, the third interlayer insulation layer 170 may be formed to cover the periphery gate structure 40P over the upper surface 101S of the substrate 101. The third interlayer insulation layer 170 may include, for example, oxide, nitride, and/or oxynitride.

Next, in the cell region I, the third interlayer insulation layer 170, the second interlayer insulation layer 150, and the etch stop layer 130 may be selectively etched to form storage node contact holes T3 exposing the second contact plugs 120b. Then, the storage node contact holes T3 may be filled with a conductive material layer to form storage node contact plugs 50.

In one embodiment, in order to form the storage node contact plugs 50, in the cell region I, the storage node contact holes T3 may be filled with the conductive material layer, and the conductive material layer may be formed over the third interlayer insulation layer 170 outside the storage node contact holes T3. The conductive material layer may also be formed over the third interlayer insulating layer 170 in the peripheral region II. Subsequently, a planarization process may be performed to remove the conductive material layer to expose the third interlayer insulating layer 170, thereby forming the storage node contact plugs 50 in the cell region I. The conductive material layer may be removed in the peripheral region II by the planarization process. The planarization process may include, for example, chemical mechanical polishing (CMP). Through the above-described method, the semiconductor device according to these embodiments of the present disclosure may be manufactured.

Capacitor elements of the semiconductor device may be formed over the storage node contact plugs 50. The capacitor element may include a storage node electrode layer, a capacitor dielectric layer, and a plate electrode layer. The storage node electrode layer may be electrically connected to the storage node contact plugs 50.

In one method of manufacturing a semiconductor device according to one embodiment of the present disclosure, the cell bit line structure may be formed by the damascene process in which the cell bit line trench formed in the first cell-periphery structure may be filled with the second cell-periphery structure. Compared to the conventional case of forming a cell bit line structure by patterning a thin film structure by etching, according to this manufacturing method according to this embodiment of the present disclosure, the cell bit line structure may be more stably formed by avoiding patterning defects. In addition, by applying the first and second cell-periphery structures to the periphery gate structures in the peripheral region, the periphery gate structures may be formed through a relatively simple process method.

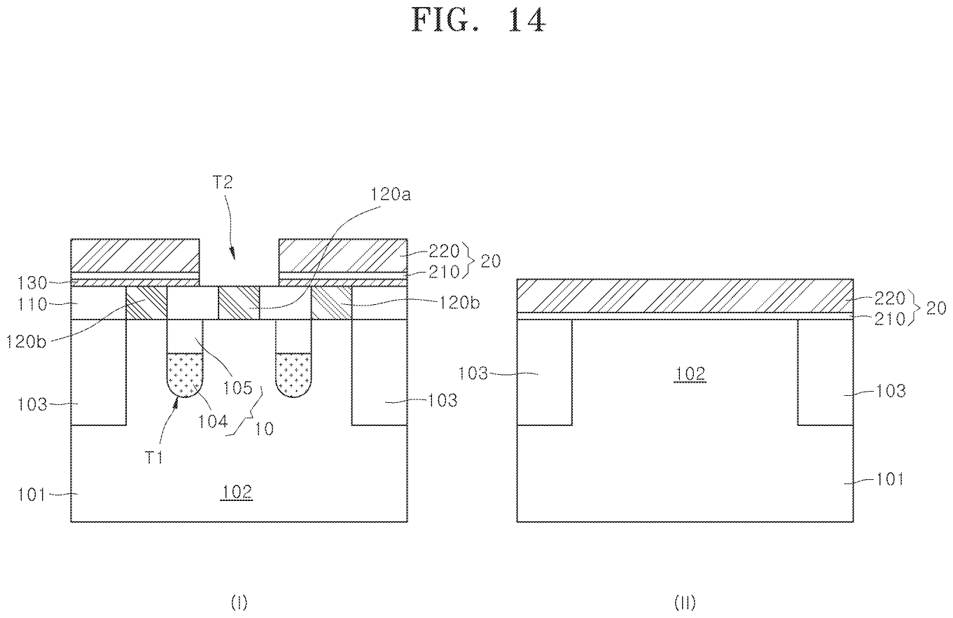

FIGS. 14 to 17 are cross-sectional views schematically illustrating another method of manufacturing a semiconductor device according to other embodiments of the present disclosure, and a semiconductor device manufactured by the method.

Referring to FIG. 14, by performing the processes described above with reference to FIGS. 2 to 7, a cell bit line trench T2 exposing a first contact plug 120a and a first interlayer insulation layer 110 over an upper surface 101S of a substrate 101 may be formed.

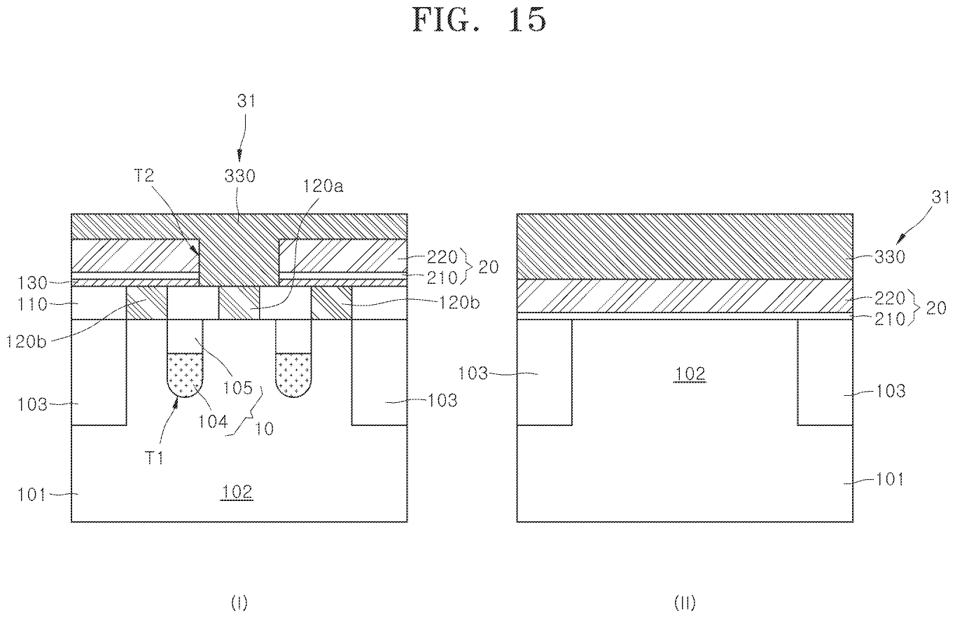

Referring to FIG. 15, a second cell-periphery structure 31 may be formed over the substrate 101. The second cell-periphery structure 31 may include a conductive layer 330. A material composition of the conductive layer 330 of the second cell-periphery structure 31 may be different from a material composition of the conductive layer 320 of the second cell-periphery structure 30 applied to the manufacturing method of the semiconductor device of FIGS. 2 to 13.

According to this embodiment, the conductive layer 330 of the second cell-periphery structure 31 may be formed of a material having an ability to fill the cell bit line trench T2 such as those listed below. In addition, the conductive layer 330 of the second cell-periphery structure 31 may be formed in a single layer.

The conductive layer 330 may include, for example, titanium (Ti), titanium nitride (TiN), tungsten nitride (WN), tungsten silicon nitride (WSiN), or a combination of two or more thereof. The material composition of the conductive layer 330 of the second cell-periphery structure 31 may be substantially the same as a material composition of the barrier layer 310 of the second cell-periphery structure 30 applied to the manufacturing method of the semiconductor device of FIGS. 2 to 13.

Referring to FIG. 15, in the cell region I, the conductive layer 330 may fill the cell bit line trench T2, and may also be formed over the first cell-periphery structure 20 outside the cell bit line trench T2. In the peripheral region II, the conductive layer 330 may be formed over the first cell-periphery structure 20.

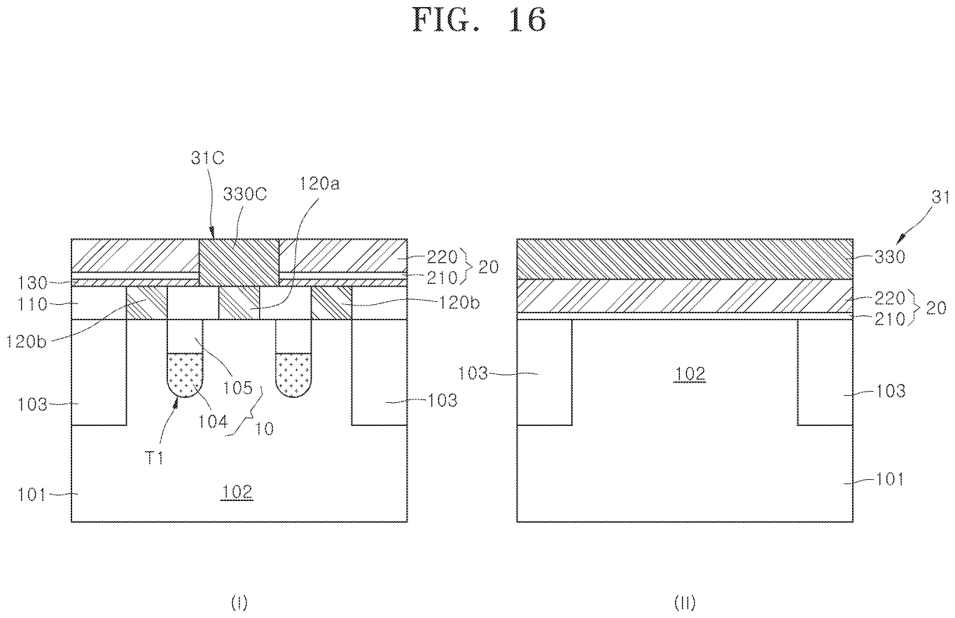

Referring to FIG. 16, a planarization process may be performed over the second cell-periphery structure 31 over the substrate 101 to form a cell bit line structure 31C. In this embodiment, in the cell region I, the second cell-periphery structure 31 (i.e., the conductive layer 330) formed outside of the cell bit line trench T2 may be removed to expose the first cell-periphery structure 20 through the planarization process. In the peripheral region II, the thickness of the conductive layer 330 may be reduced through the planarization process. As a result of the planarization process, the cell bit line structure 31C in the cell region I may include a bit line conductive layer 330C.

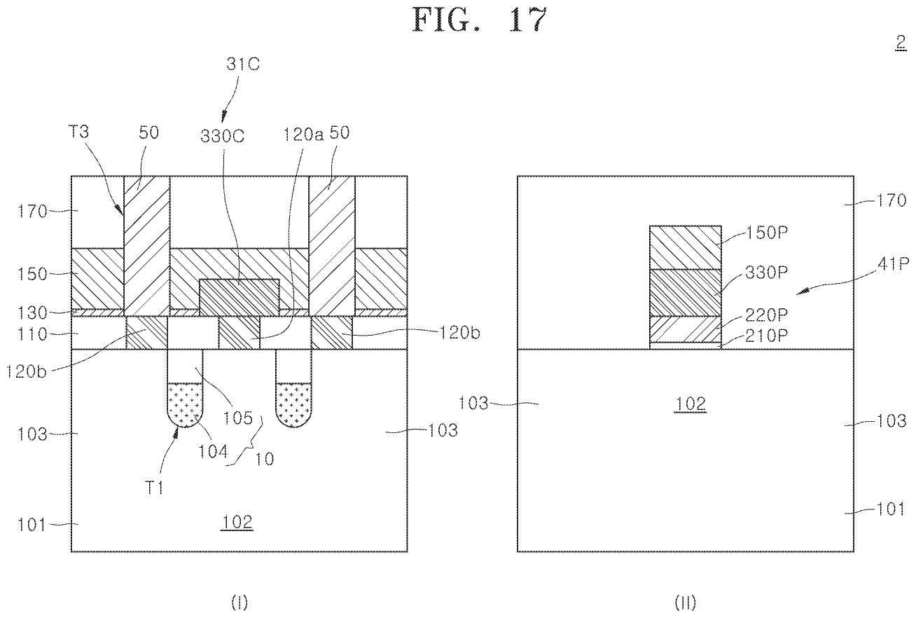

Subsequently, a semiconductor device 2 shown in FIG. 17 may be manufactured by performing the processes described above with reference to FIGS. 10 to 13. Compared to the semiconductor device 1 described above with reference to FIG. 1, in the semiconductor device 2, the cell bit line structure 31C may include a conductive material having an ability to fill the cell bit line trench T2 such as for example titanium (Ti), titanium nitride (TiN), tungsten nitride (WN), tungsten silicon nitride (WSiN), or a combination of two or more thereof. Meanwhile, in FIGS. 15 to 17, the cell bit line structure 31C is formed as a single material layer, but in another embodiment of the present disclosure, the cell bit line structure 31C may be formed as a plurality of material layers having an ability to fill the cell bit line trench T2. In this case, some of the plurality of material layers may function as the bit line diffusion barrier layer, and others may function as the bit line conductive layer.

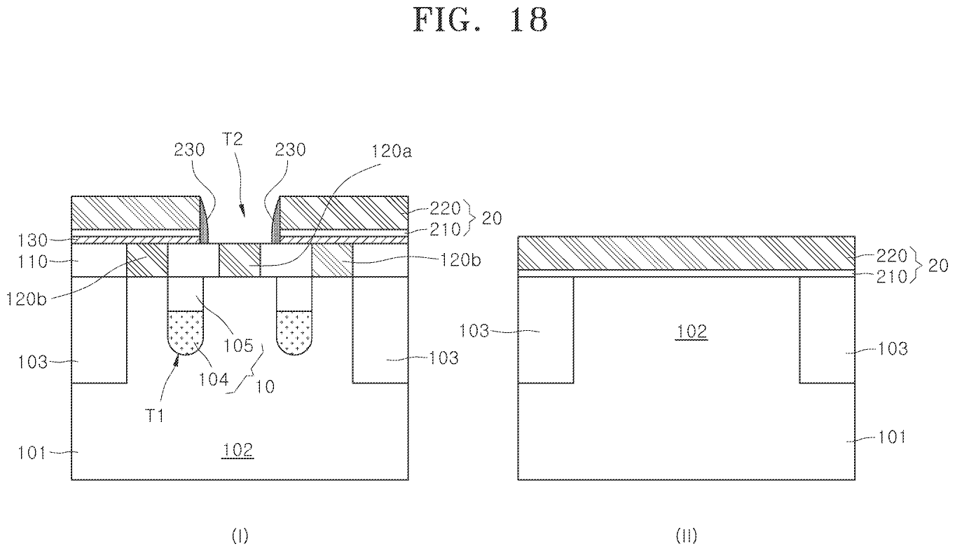

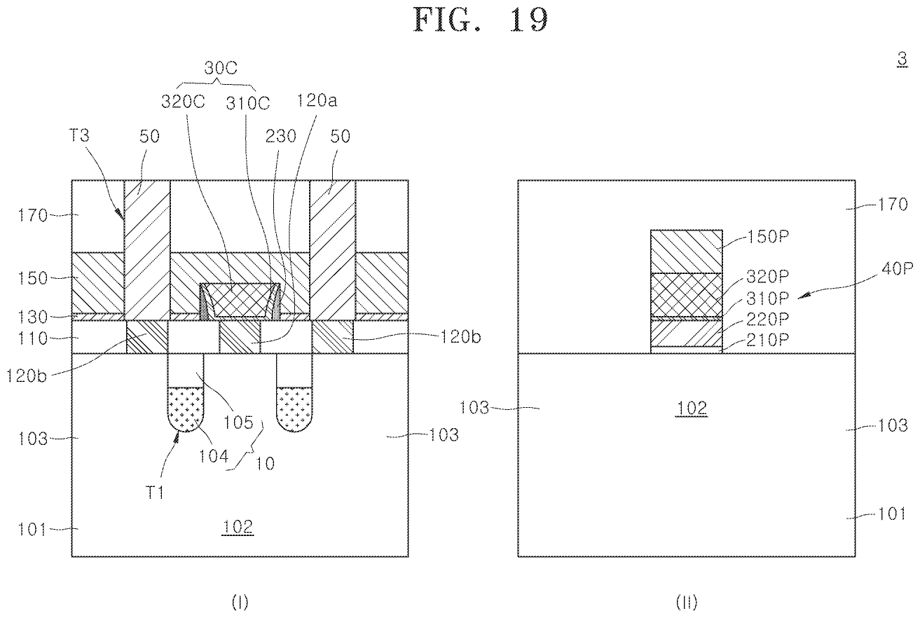

FIGS. 18 and 19 are cross-sectional views schematically illustrating a method of manufacturing a semiconductor device according to further embodiments of the present disclosure.

Referring to FIG. 18, by performing the processes described above with reference to FIGS. 2 to 7, a cell bit line trench T2 exposing a first contact plug 120a and a first interlayer insulating layer 110 may be formed in the cell region I. Subsequently, a bit line spacer 230 including an insulating material may be formed on a sidewall surface of the cell bit line trench T2. The insulating material may have a dielectric constant equal to or lower than that of silicon oxide.

Subsequently, a semiconductor device 3 shown in FIG. 19 may be manufactured by performing the processes described above with reference to FIGS. 8 to 13. Unlike the semiconductor device 1 described above with reference to FIG. 1, the semiconductor device 3 may further include the bit line spacer 230 formed on the sidewall surface of the cell bit line trench T2.

In the case of the semiconductor device 1 of FIG. 1, the bit line diffusion barrier layer 310C of the cell bit line structure 30C may contact the second interlayer insulation layer 150 including nitride. In contrast, in the case of the semiconductor device 3, the bit line diffusion barrier layer 310C of the cell bit line structure 30C may contact the bit line spacer 230 having the low dielectric constant. Accordingly, with the presence of the bit line spacer 230, a parasitic capacitance occurring between the cell bit line structure 30C and an adjacent conductive layer (e.g., the storage node contact plugs 50 or another cell bit line structure 30C) may be reduced. In addition, by the bit line spacer 230 improving insulation between the cell bit line structure 30C and the storage node contact plugs 50 adjacent to each other, the electrical conduction between the cell bit line structure 30C and the storage node contact plugs 50 may be prevented from occurring.

In one method of manufacturing a semiconductor device according to various embodiments of the present disclosure, a substrate having a first region and a second region may be provided. In one embodiment, the first region may include a cell region, and the second region may include a peripheral region.

This method of manufacturing the semiconductor device may include forming a first structure including a first conductive layer over a surface of the substrate or over the entirety of the substrate. In another embodiment, the first structure may include a first cell-periphery structure covering the cell region and the peripheral region.

This method of manufacturing the semiconductor device may include forming a trench in the first region by patterning the first structure. In another embodiment, forming the trench may include forming a cell bit line trench in the cell region.

This method of manufacturing the semiconductor device may include forming a second structure including a second conductive layer over the surface of the substrate or over the entirety of the substrate. The second structure may form a first conductive line structure filling the trench in the first region, and may be disposed over the first structure in the second region. In another embodiment, the second structure may include a second cell-periphery structure covering the cell region and the peripheral region. In another embodiment, second cell-periphery structure may form a cell bit line structure filling the cell bit line trench in the cell region, and may be disposed over the first cell-periphery structure in the peripheral region.

This method of manufacturing the semiconductor device may include forming a second conductive line structure by patterning the first and second structures in the second region. In another embodiment, forming the second conductive line structure may include forming the periphery gate structure by patterning the first and second cell-periphery structures.

Accordingly, this method of manufacturing a semiconductor device according to another embodiment of the present disclosure may provide a method of stably forming the first conductive line structure of the first region and the second conductive line structure of the second region using the first and second structures.

Concepts have been disclosed in conjunction with the embodiments described above. Those skilled in the art will appreciate that various modifications, additions, and substitutions are possible, without departing from the scope of the present disclosure. Accordingly, the embodiments disclosed in the present specification should be considered from not a restrictive standpoint but rather from an illustrative standpoint. The scope of the concepts is not limited to the above descriptions, and all of distinctive features in the equivalent scope should be construed as being included in the present disclosure.

What is claimed is:

1. A method of manufacturing a semiconductor device, the method comprising:
providing a substrate having a cell region and a peripheral region;
forming a first cell-periphery structure including a conductive layer over a surface of the substrate;
forming a cell bit line trench by patterning the first cell-periphery structure in the cell region;
forming a second cell-periphery structure including a second conductive layer over the surface of the substrate, wherein the second cell-periphery structure forms a cell bit line structure filling the cell bit line trench in the cell region, and wherein the second cell-periphery structure including the second conductive layer is disposed over the first cell-periphery structure in the peripheral region; and
forming a periphery gate structure by patterning the first and second cell-periphery structures in the peripheral region.

2. The method of claim 1, wherein forming the first cell-periphery structure includes:
forming a dielectric layer over the substrate in the cell region and the peripheral region; and
forming the first conductive layer over the dielectric layer.

3. The method of claim 2,
wherein the dielectric layer includes at least one or more of silicon oxide, silicon nitride, silicon oxynitride, aluminum oxide, hafnium oxide, zirconium oxide, and hafnium zirconium oxide, and
wherein the first conductive layer includes polysilicon.

4. The method of claim 1, wherein the first cell-periphery structure further includes a periphery gate dielectric layer formed between the substrate and the first conductive layer in the peripheral region.

5. The method of claim 1, wherein forming the cell bit line structure includes:
forming a barrier layer along an inner surface of the cell bit line trench in the cell region; and
filling the cell bit line trench in which the barrier layer is formed with the second conductive layer.

6. The method of claim 5,
wherein the barrier layer includes at least one or more of titanium (Ti), titanium nitride (TiN), tungsten nitride (WN), and tungsten silicon nitride (WSiN), and
wherein the second conductive layer includes tungsten (W).

7. The method of claim 1,
wherein forming the cell bit line structure includes filling the cell bit line trench with the second conductive layer in the cell region, and
wherein the second conductive layer includes at least one or more of titanium (Ti), titanium nitride (TiN), tungsten nitride (WN), and tungsten silicon nitride (WSiN).

8. The method of claim 1, further comprising performing a planarization process over the second cell-periphery structure after forming the second cell-periphery structure,
wherein in the planarization process, the second cell-periphery structure formed outside the cell bit line trench is removed to expose the first cell-periphery structure in the cell region.

9. The method of claim 1, further comprising removing the first cell-periphery structure in the cell region after forming the second cell-periphery structure.

10. The method of claim 1, further comprising forming a bit line spacer including an insulation layer on a sidewall surface of the cell bit line trench, after forming the cell bit line trench.

11. The method of claim 1, further comprising:
forming a cell gate structure buried in the substrate in the cell region; and
forming a cell contact plug and an interlayer insulation layer surrounding the cell contact plug over the substrate in the cell region,
wherein the cell contact plug electrically connects the substrate and the cell bit line structure to each other.

12. A method of manufacturing a semiconductor device, the method comprising:
providing a substrate having a cell region and a peripheral region;
forming a cell gate structure buried in the substrate in the cell region;
forming a cell contact plug and an interlayer insulation layer surrounding the cell contact plug over the substrate in the cell region;
forming a first cell-periphery structure including a first conductive layer over a surface of the substrate;
forming a cell bit line trench exposing the cell contact plug by patterning the first cell-periphery structure in the cell region;
forming a second cell-periphery structure including a second conductive layer over the surface of the substrate, wherein the second cell-periphery structure forms a cell bit line structure filling the cell bit line trench in the cell region, and wherein the second cell-periphery structure including the second conductive layer is disposed over the first cell-periphery structure in the peripheral region;
removing the first cell-periphery structure in the cell region; and
forming a periphery gate structure by patterning the first and second cell-periphery structures in the peripheral region.

13. The method of claim 12, wherein forming the first cell-periphery structure includes:
forming a dielectric layer over the substrate in the cell region and the peripheral region; and
forming the first conductive layer over the dielectric layer.

14. The method of claim 13,
wherein the dielectric layer includes at least one or more of silicon oxide, silicon nitride, silicon oxynitride, aluminum oxide, hafnium oxide, zirconium oxide, and hafnium zirconium oxide, and
wherein the first conductive layer includes polysilicon.

15. The method of claim 12, wherein forming the cell bit line structure includes:
forming a barrier layer along an inner surface of the cell bit line trench in the cell region; and
filling the cell bit line trench in which the barrier layer is formed with the second conductive layer.

16. The method of claim 15,
wherein the barrier layer includes at least one or more of titanium (Ti), titanium nitride (TiN), tungsten nitride (WN), and tungsten silicon nitride (WSiN), and
wherein the second conductive layer includes tungsten (W).

17. The method of claim 12,
wherein forming the cell bit line structure includes filling the cell bit line trench with the second conductive layer in the cell region, and
wherein the second conductive layer includes at least one or more of titanium (Ti), titanium nitride (TiN), tungsten nitride (WN), and tungsten silicon nitride (WSiN).

18. The method of claim 12, further comprising performing a planarization process over the second cell-periphery structure after forming the second cell-periphery structure,
wherein in the planarization process, the second cell-periphery structure formed outside the cell bit line trench is removed to expose the first cell-periphery structure in the cell region.

19. The method of claim 12, further comprising forming a bit line spacer including an insulation layer on a sidewall surface of the cell bit line trench, after forming the cell bit line trench.

20. The method of claim 12, further comprising forming an interlayer insulation layer over the entire surface of the substrate after removing the first cell-periphery structure in the cell region,
wherein forming the periphery gate structure further includes patterning the interlayer insulation layer.

21. A method of manufacturing a semiconductor device, the method comprising:
providing a substrate having a first region and a second region;
forming a first structure including a first conductive layer over a surface of the substrate;
forming a trench by patterning the first structure in the first region;
forming a second structure including a second conductive layer over the surface of the substrate, wherein the second structure forms a first conductive line structure filling the trench in the first region, and wherein the second structure including the second conductive layer is disposed over the first structure in the second region; and
forming a second conductive line structure by patterning the first and second structures in the second region.

22. The method of claim 21, wherein the first region includes a cell region, and the second region includes a peripheral region.

23. The method of claim 22, wherein forming the first conductive line structure includes forming a cell bit line structure in the cell region.

24. The method of claim 22, wherein forming the second conductive line structure includes forming a periphery gate structure in the peripheral region.
